(19) United States
(12) Patent Application Publication
(10) Pub. No.: US 2026/0186535 A1
(43) Pub. Date: Jul. 2, 2026

(54) DISPLAY DEVICE

(71) Applicant: LG DISPLAY CO., LTD., SEOUL (KR)

(72) Inventors: GyuHo Lee, Seoul (KR); Sinchul Kang, Gimpo-si (KR)

(21) Appl. No.: 19/254,152

(22) Filed: Jun. 30, 2025

(30) Foreign Application Priority Data
Dec. 30, 2024 (KR) 10-2024-0201382

(51) Int. Cl. G06F 1/16; G02F 1/1333; H10K 59/80; H10K 102/00

(52) U.S. Cl. CPC G06F 1/1652; G02F 1/133331; H10K 59/87; H10K 2102/311

(57) ABSTRACT

A display device includes a display area and a non-display area including a first non-display area adjacent to the display area, a bending area extending from at least one side of the first non-display area, and a second non-display area extending from one side of the bending area, the display device including: a first glass substrate in the display area; a second glass substrate in the second non-display area; an anti-etching layer overlapping the bending area; a link line on the anti-etching layer and traversing the bending area; an upper micro-coating layer disposed on the link line in the bending area, and at least partially overlapping the first non-display area and the second non-display area; a first lower micro-coating layer disposed below the anti-etching layer in the bending area; and a second lower micro-coating layer disposed below the first lower micro-coating layer in the bending area.

### CROSS-REFERENCE TO RELATED APPLICATIONS

Pursuant to 35 U.S.C. § 119 (a), this application claims the benefit of an earlier filing date and right of priority to Korean Patent Application No. 10-2024-0201382 filed on Dec. 30, 2024 in the Korean Intellectual Property Office, the disclosure of which is incorporated herein by reference in its entirety.

### TECHNICAL FIELD

The present disclosure relates to a display device.

### BACKGROUND

In general, display devices are widely used for display screens of various electronic devices such as mobile communication terminals, electronic notebooks, electronic books, portable multimedia players (PMP), navigation systems, ultra-mobile PCs (UMPCs), mobile phones, smartphones, tablet personal computers (PCs), watch phones, electronic pads, wearable devices, portable information devices, vehicle control display devices, televisions, laptop computers, and monitors.

Recently, research and development have been conducted on display devices that can maximize screen sizes on display panels of a given size by reducing bezel areas where images are not displayed.

### SUMMARY

A display device according to an implementation of the present specification may include a display area and a non-display area including a first non-display area adjacent to the display area, a bending area extending from at least one side of the first non-display area, and a second non-display area extending from one side of the bending area, the display device including: a first glass substrate disposed in the display area; a second glass substrate disposed in the second non-display area; an anti-etching layer disposed to overlap the bending area; a link line disposed on the anti-etching layer and traversing the bending area; an upper micro-coating layer disposed on the link line in the bending area and disposed to at least partially overlap the first non-display area and the second non-display area; a first lower micro-coating layer disposed below the anti-etching layer in the bending area; and a second lower micro-coating layer disposed below the first lower micro-coating layer in the bending area.

Other detailed matters of the example implementations are included in the detailed description and the drawings.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a top plan view of a display device according to an implementation of the present specification;

FIG. 2 is a cross-sectional view of a display area of the display device according to the implementation of the present specification;

FIG. 3A is a cross-sectional view taken along line A-A′ in FIG. 1 in a state before a bending process;

FIG. 3B is a cross-sectional view taken along line A-A′ in FIG. 1 in a state after the bending process;

FIGS. 4A to 4C are views illustrating results of simulations on stress on a display device according to a comparative example;

FIG. 5 is a cross-sectional view illustrating a display device according to another implementation of the present specification in a state after a bending process;

FIG. 6A is a top plan view of a display device according to still yet another implementation of the present specification;

FIG. 6B is an enlarged view of area B in FIG. 6A;

FIG. 6C is a cross-sectional view taken along line B-B′ in FIG. 6B in a state before the bending process;

FIG. 7 is an enlarged top plan view of a display device according to yet another implementation of the present specification; and

FIG. 8 is an enlarged top plan view of a display device according to still yet another implementation of the present specification.

### DETAILED DESCRIPTION

Implementations are disclosed herein that provide a display device capable of reducing stress during a bezel bending process and improving external impact absorbability.

Implementations of the present disclosure can provide a display device capable of minimizing a width of a bezel area.

Implementations of the present disclosure can provide a display device capable of reducing stress caused by a micro-coating layer during a bezel bending process.

Implementations of the present disclosure can provide a display device capable of reducing stress applied to a bending area and improving reliability.

Implementations of the present disclosure can provide a display device capable of improving durability against external impact by ensuring mechanical rigidity of a bending area.

According to implementations of the present specification, it is possible to reduce the thickness of the existing upper micro-coating layer in the bending area during the bezel bending process and reduce bending stress by introducing the lower micro-coating layer.

According to implementations of the present specification, the plurality of lower micro-coating layers cured by the different processes may reduce the thickness of the bezel area and reduce the radius of curvature of the bending area.

According to implementations of the present specification, the lower micro-coating layers having different moduli may improve the external impact absorbability, thereby improving the impact resistance.

According to implementations of the present specification, it is possible to adjust the bending shape and maintain the reliable environment and shape during the bending process.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

The effects according to the present disclosure are not limited to the contents exemplified above, and more various effects are included in the present specification.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various implementations of the present disclosure can be partially or entirely adhered to or combined with each other and can be interlocked and operated in technically various ways, and the implementations can be carried out independently of or in association with each other.

Hereinafter, a display device according to example implementations of the present disclosure will be described in detail with reference to accompanying drawings.

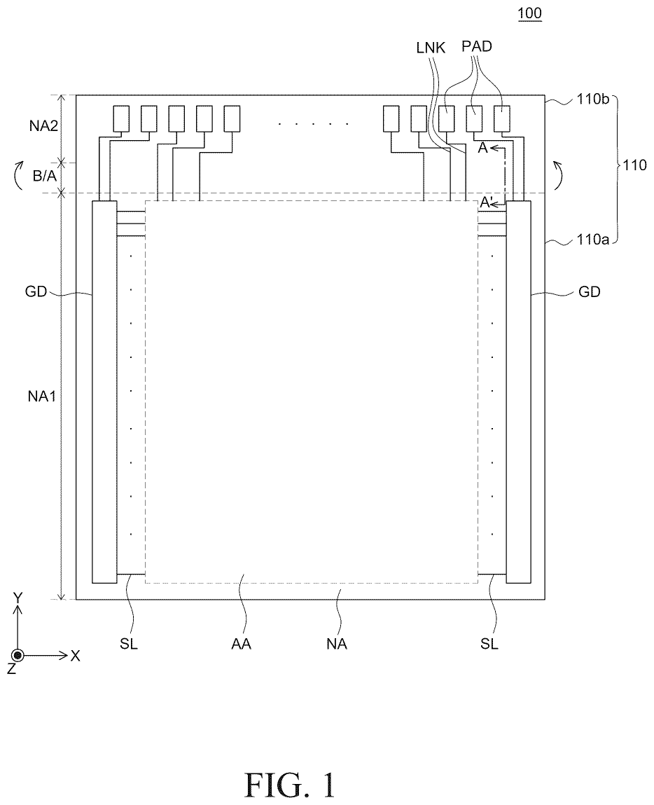

FIG. 1 is a top plan view of a display device according to an implementation of the present specification.

With reference to FIG. 1, a glass substrate 110 of a display device 100 according to an implementation of the present specification includes a display area (active area) AA in which subpixels configured to actually emit light by means of thin-film transistors and light-emitting elements are disposed, and a non-display area (non-active area) NA configured to surround an outer periphery of the display area AA.

The display area AA may be an area in which a plurality of subpixels is disposed to display images. The plurality of subpixels are each an individual unit configured to emit light. A display element and a drive circuit may be formed on each of the plurality of subpixels. For example, the display element for displaying an image and a circuit part for operating the display element may be disposed in each of the plurality of subpixels. In this case, in case that the display device 100 is an organic light-emitting display device, the display element may include an organic light-emitting element. In case that the display device 100 is a liquid crystal display device, the display element may include a liquid crystal element. The plurality of subpixels may include a red subpixel, a green subpixel, a blue subpixel, and a white subpixel. However, the present specification is not limited thereto. The drive circuit may include various thin-film transistors, storage capacitors, and lines for operating the plurality of subpixels. For example, the drive circuit may include various constituent elements such as a driving thin-film transistor, a switching thin-film transistor, a sensing thin-film transistor, a storage capacitor, a gate line, and a data line. However, the present specification is not limited thereto.

Circuits, such as a gate driver GD, for operating the display device 100 and various signal lines, such as a scan line SL that is a gate line, may be disposed in the non-display area NA. Further, the gate driver GD for operating the display device 100 may be disposed on the glass substrate 110 in a gate-in-panel (GIP) manner or connected to the glass substrate 110 in a tape-carrier-package (TCP) or chip-on-film (COF) manner.

The non-display area NA may include a first non-display area NA1 adjacent to the display area AA, a bending area BA extending from the first non-display area NA1, and a second non-display area NA2 extending from one side of the bending area BA.

Specifically, the first non-display area NA1 is an area in which no image is displayed. The first non-display area NA1 is disposed to surround the display area AA. The first non-display area NA1 may be an area in which various lines, drive ICs, and the like for operating the plurality of subpixels disposed in the display area AA are disposed. The first non-display area NA1, in which no image is displayed, may be a bezel area. However, the implementations of the present specification are not limited thereto.

A part of the non-display area NA may be bent in a bending direction indicated by the arrows illustrated in FIG. 1. The area, which is bent as described above, may be referred to as the bending area BA. In other words, the bending area BA may be a part of the first non-display area NA1 extending from one side of the non-display area NA. The bending area BA may be an area to be bent.

Pad parts PAD may be disposed in the second non-display area NA2 extending from one side of the bending area BA. The pad parts PAD may include a plurality of pad electrodes to which an external module is bonded.

Various lines are formed on the glass substrate 110. The lines may be disposed in the display area AA of the glass substrate 110 and also be disposed in the non-display area NA. In particular, link lines LNK formed in the non-display area NA may be connected to the drive circuit, e.g., the gate driver GD, the data driver, or the like and transmit signals.

The link line LNK may be made of an electrically conductive material. The link line LNK may be made of an electrically conductive material having excellent flexibility in order to reduce the occurrence of cracks when the glass substrate 110 is bent. For example, the link line LNK may be made of an electrically conductive material such as gold (Au), silver (Ag), or aluminum (Al) that has excellent flexibility. The link line LNK may be made of one of various electrically conductive materials used in the display area AA. The link line LNK may be made of an alloy of molybdenum (Mo), chromium (Cr), titanium (Ti), nickel (Ni), neodymium (Nd), copper (Cu), silver (Ag), and magnesium (Mg). Further, the link line LNK may be configured as a multilayer structure including various electrically conductive materials. For example, the link line LNK may be configured as a three-layer structure including titanium (Ti), aluminum (Al), and titanium (Ti). However, the structure of the link line LNK according to the present specification is not limited thereto.

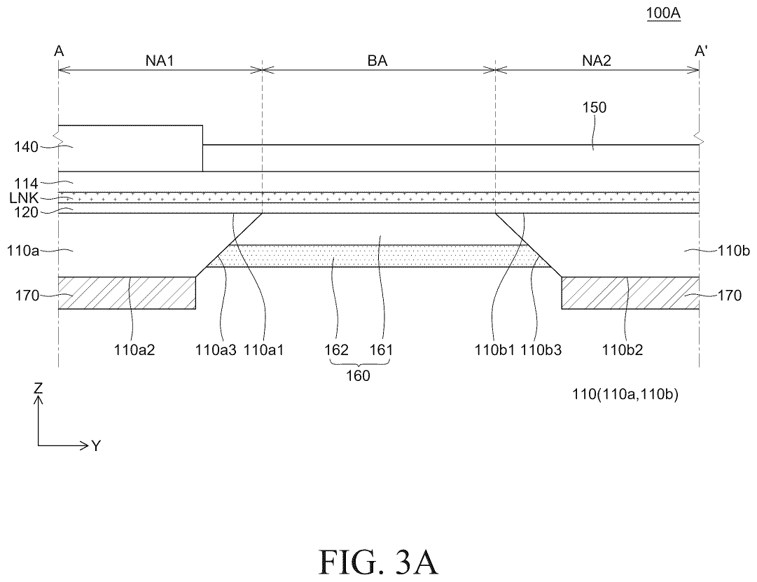

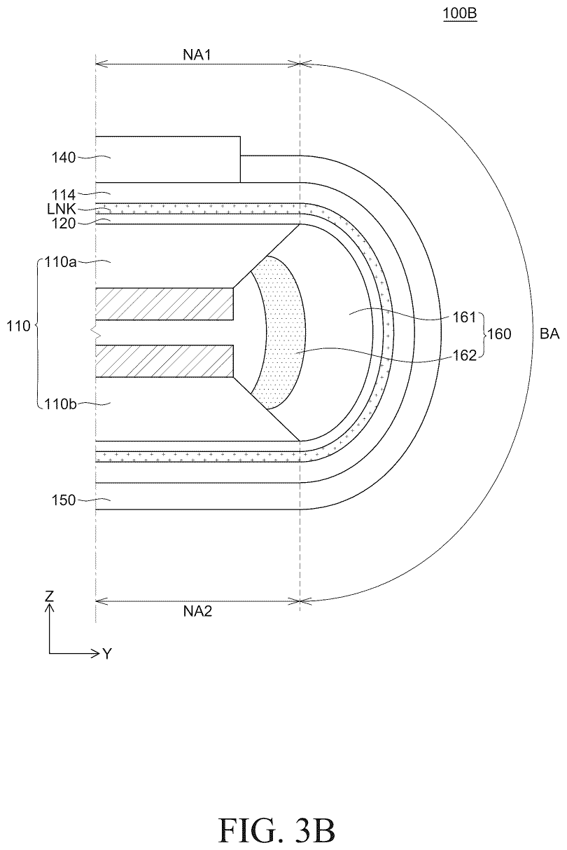

A tensile force is applied to the link line LNK formed in the bending area BA when the bending area BA is bent. For example, the link line LNK, which extends in a direction identical to the bending direction (indicated by the arrows) on the glass substrate 110, may receive the highest tensile force, which may cause cracks. A line disconnection may occur when cracks are severe. Therefore, as described below, an upper micro-coating layer is disposed above the link line LNK and a plurality of lower micro-coating layers are disposed below the link line LNK while corresponding to the bending area BA, such that bending stress may be reduced, a tensile force may be minimized, and the occurrence of a crack may be minimized. The upper micro-coating layer and the plurality of lower micro-coating layers will be described below in detail with reference to FIGS. 3A and 3B.

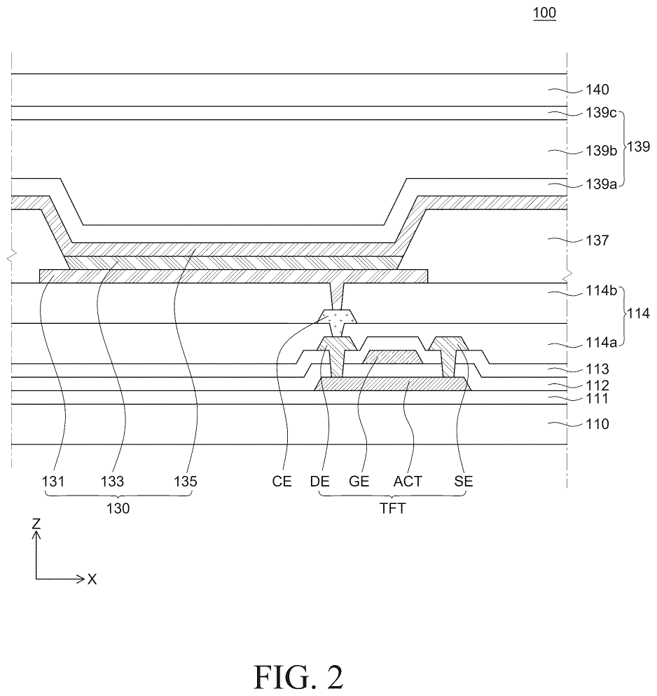

FIG. 2 is a cross-sectional view of the display area of the display device according to the implementation of the present specification.

With reference to FIG. 2, the display device 100 includes the glass substrate 110, a thin-film transistor TFT, a connection electrode CE, and a light-emitting element 130.

The glass substrate 110 serves to support and protect constituent elements of the display device 100 that are disposed above the glass substrate 110. The glass substrate 110 may be made of glass.

A buffer layer 111 is disposed on the glass substrate 110. The buffer layer 111 may suppress the permeation of moisture or other impurities through the glass substrate 110 and planarize a surface of the glass substrate 110. The buffer layer 111 is not a necessarily essential component and may be excluded depending on the type of thin-film transistor TFT disposed on the glass substrate 110.

The thin-film transistor TFT is disposed on the glass substrate 110. The thin-film transistor TFT may operate the light-emitting element 130. The thin-film transistor TFT includes a gate electrode GE, a source electrode SE, a drain electrode DE, and a semiconductor layer ACT.

The semiconductor layer ACT is disposed on the buffer layer 111. The semiconductor layer ACT is an area in which a channel is formed when the thin-film transistor TFT operates.

The semiconductor layer ACT may be made of amorphous silicon. Alternatively, the semiconductor layer ACT may be made of polycrystalline silicon that has better mobility and reliability and requires lower energy power consumption than amorphous silicon and thus may be applied to a driving thin-film transistor in a pixel. However, the present specification is not limited thereto.

The semiconductor layer ACT may be made of an oxide semiconductor. The oxide semiconductor is excellent in mobility and uniformity properties. For example, the semiconductor layer ACT may be made of the oxide semiconductor made of materials based on indium-tin-gallium-zinc oxide (InSnGaZnO) which is quaternary metal oxide, materials based on indium-gallium-zinc oxide (InGaZnO), indium-tin-zinc oxide (InSnZnO), indium-aluminum-zinc oxide (InAlZnO), tin-gallium-zinc oxide (SnGaZnO), aluminum-gallium-zinc oxide (AlGaZnO), and tin-aluminum-zinc oxide (SnAlZnO) which are ternary metal oxide, materials based on indium-zinc oxide (InZnO), tin-zinc oxide (SnZnO), aluminum-zinc oxide (AlZnO), zinc-magnesium oxide (ZnMgO), tin-magnesium oxide (SnMgO), indium-magnesium oxide (InMgO), and indium-gallium oxide (InGaO) which are binary metal oxide, and materials based on indium oxide (InO), tin oxide (SnO), and zinc oxide (ZnO). The present specification is not limited to a composition ratio of the respective elements.

The semiconductor layer ACT may include source and drain regions including p-type or n-type impurities and a channel region between the source region and the drain region. The semiconductor layer ACT may further include a low-concentration doping region between the source and drain regions adjacent to the channel region.

The source and drain regions are regions doped with impurities at high concentration. The source electrode SE and the drain electrode DE of the thin-film transistor TFT may be respectively connected to the source and drain regions. The p-type impurities or the n-type impurities may be used as impurities ions. For example, the p-type impurity may be one of boron (B), aluminum (Al), gallium (Ga), and indium (In). For example, the n-type impurity may be one of phosphorus (P), arsenic (As), and antimony (Sb).

According to a structure of an NMOS or PMOS thin-film transistor, the channel area of the semiconductor layer ACT may be doped with n-type impurities or p-type impurities. The NMOS or PMOS thin-film transistor may be applied as the thin-film transistor included in the electroluminescent display device according to the implementation of the present specification.

A first insulation layer 112 is an insulation layer for insulating the semiconductor layer ACT and the gate electrode GE. The first insulation layer 112 is an insulation layer configured as a single layer or multilayer made of silicon oxide (SiOx) or silicon nitride (SiNx). The first insulation layer 112 is disposed such that an electric current flowing in the semiconductor layer ACT does not flow to the gate electrode GE. Further, the silicon oxide has lower flexibility than metal but has higher flexibility than silicon nitride. A single layer or multilayer made of silicon oxide may be implemented in accordance with the properties of the silicon oxide.

The gate electrode GE may serve as a switch configured to turn on or off the thin-film transistor TFT on the basis of an electrical signal transmitted from the outside through the gate line. For example, the gate electrode GE may be configured as a single layer or multilayer made of a conductive metallic material such as copper (Cu), aluminum (Al), molybdenum (Mo), chromium (Cr), gold (Au), titanium (Ti), nickel (Ni), neodymium (Nd), or an alloy thereof. However, the present specification is not limited thereto.

The source electrode SE and the drain electrode DE is connected to the data line and allows the electrical signal transmitted from the outside to be transmitted from the thin-film transistor TFT to the light-emitting element 130. For example, the source electrode SE and the drain electrode DE may each be configured as a single layer or multilayer made of a conductive metallic material such as copper (Cu), aluminum (Al), molybdenum (Mo), chromium (Cr), gold (Au), titanium (Ti), nickel (Ni), neodymium (Nd), or an alloy thereof. However, the present specification is not limited thereto.

A second insulation layer 113 configured as a single layer or multilayer made of silicon oxide (SiOx) or silicon nitride (SiNx) may be disposed between the gate electrode GE, the source electrode SE, and the drain electrode DE in order to insulate the gate electrode GE, the source electrode SE, and the drain electrode DE from one another. The source electrode SE and the drain electrode DE are electrically connected to the semiconductor layer ACT through contact holes of the first and second insulation layers 112 and 113.

A passivation layer configured as an inorganic insulation layer made of silicon oxide (SiOx) or silicon nitride (SiNx) may be further disposed on the thin-film transistor TFT. The passivation layer may serve to suppress unnecessary electrical connection between the constituent elements disposed above and below the passivation layer. The passivation layer may also serve to suppress damage or contamination from the outside. The passivation layer may be excluded in accordance with the configurations and properties of the thin-film transistor TFT and the light-emitting element 130.

The structures of the thin-film transistor TFT may be classified into an inverted staggered structure and a coplanar structure depending on the positions of the constituent elements that constitute the thin-film transistor TFT. In the case of the thin-film transistor having the inverted staggered structure, the gate electrode is positioned at a side opposite to the source electrode and the drain electrode based on the semiconductor layer. As illustrated in FIG. 2, in the case of the thin-film transistor TFT having the coplanar structure, the gate electrode GE is positioned at the same side as the source electrode SE and the drain electrode DE based on the semiconductor layer ACT.

FIG. 2 illustrates the thin-film transistor TFT having the coplanar structure. However, the present specification is not limited thereto. The display device 100 according to the present specification may include the thin-film transistor having the inverted staggered structure.

For convenience of description, FIG. 2 illustrates only a driving thin-film transistor among various thin-film transistors that may be included in the display device 100. However, a switching thin-film transistor, a capacitor, and the like may also be included in the display device 100. Further, when a signal is applied from the gate line, the switching thin-film transistor transmits the signal from the data line to the gate electrode of the driving thin-film transistor. In response to a signal received from the switching thin-film transistor, the driving thin-film transistor transmits an electric current, which is transmitted through the power line, to an anode 131. The driving thin-film transistor controls light emission on the basis of the electric current transmitted to the anode 131.

A planarization layer 114 is disposed on the thin-film transistor TFT to protect the thin-film transistor TFT, reduce a level difference caused by the thin-film transistor TFT, and reduce parasitic capacitance occurring between the thin-film transistor TFT, the gate line, the data line, and the light-emitting elements 130.

The planarization layer 114 is an insulation layer for planarizing an upper portion of the glass substrate 110. The planarization layer 114 may be made of an organic material. For example, the planarization layer 114 may be one or more materials among acrylic resin, epoxy resin, phenolic resin, polyamide-based resin, polyimide-based resin, unsaturated polyester-based resin, polyphenylene-based resin, polyphenylene sulfide-based resin, and benzocyclobutene. However, the present specification is not limited thereto.

The display device 100 according to the implementation of the present specification may include a first planarization layer 114a and a second planarization layer 114b that are the plurality of planarization layers 114 stacked sequentially.

For example, the first planarization layer 114a may be disposed on the thin-film transistor TFT, and the second planarization layer 114b may be disposed on the first planarization layer 114a.

Further, the buffer layer may be disposed on the first planarization layer 114a. The buffer layer may be disposed to protect the constituent elements disposed on the first planarization layer 114a. For example, the buffer layer may be configured as a single layer made of silicon nitride (SiNx) or silicon oxide (SiOx) or a multilayer made of silicon nitride (SiNx) or silicon oxide (SiOx). The buffer layer may be excluded in accordance with the configurations and properties of the thin-film transistor TFT and the light-emitting element 130.

The connection electrode CE is disposed through a contact hole formed in the first planarization layer 114a, and the connection electrode CE is electrically connected to the thin-film transistor TFT. That is, the connection electrode CE is an electrode configured to connect the drain electrode DE of the thin-film transistor TFT and the anode 131 of the light-emitting element 130. The connection electrode CE may be configured as a multilayer made of an electrically conductive material, e.g., copper (Cu), gold (Au), silver (Ag), aluminum (Al), molybdenum (Mo), nickel (Ni), titanium (Ti), chromium (Cr), or an alloy thereof. However, the present specification is not limited thereto.

The passivation layer configured as an inorganic insulation layer made of silicon oxide (SiOx) or silicon nitride (SiNx) may be further disposed on the first planarization layer 114a and the connection electrode CE. The passivation layer may serve to suppress unnecessary electrical connection between the components. The passivation layer may also serve to inhibit damage or contamination from the outside. The passivation layer may be excluded in accordance with the configurations and properties of the thin-film transistor TFT and the light-emitting element 130.

The light-emitting element 130 is disposed on the second planarization layer 114b, and the light-emitting element 130 includes the anode 131, a light-emitting layer 133, and a cathode 135.

The anode 131 may be disposed on the second planarization layer 114b. The anode 131 is an electrode that serves to supply positive holes to the light-emitting layer 133. The anode 131 is connected to the connection electrode CE through a contact hole, which is formed in the second planarization layer 114b, and electrically connected to the thin-film transistor TFT through the connection electrode CE.

For example, the anode 131 may be made of a transparent, electrically conductive material such as indium tin oxide (ITO) and indium zinc oxide (IZO). However, the present specification is not limited thereto.

In case that the display device 100 according to the present specification is a top emission type that emits light toward an upper side at which the cathode 135 is disposed, the anode 131 may further include a reflective layer so that the emitted light may be reflected by the anode 131 and more smoothly discharged to the upper side at which the cathode 135 is disposed.

For example, the anode 131 may have a two-layer structure in which a reflective layer and a transparent conductive layer made of a transparent electrically conductive material are sequentially stacked. Alternatively, the anode 131 may have a three-layer structure in which the transparent conductive layer, the reflective layer, and the transparent conductive layer are sequentially stacked. The reflective layer may be made of an alloy containing silver (Ag).

A bank layer 137 is disposed on the anode 131 and the second planarization layer 114b. The bank layer 137 may define the pixel by dividing the area in which light is actually emitted. The bank layer 137 may be formed by forming a photoresist on the anode 131 and performing photolithography. The photoresist refers to photosensitive resin having solubility that is changed in respect to a developer by the action of light. A particular pattern may be obtained by exposing and developing the photoresist. The photoresists may be classified into a positive photoresist and a negative photoresist. The positive photoresist refers to a photoresist in which solubility of an exposed part in respect to a developer is increased by exposure. When the positive photoresist is developed, a pattern from which the exposed part is removed is obtained. Further, the negative photoresist refers to a photoresist in which solubility of an exposed part in respect to a developer is decreased by exposure. When the negative photoresist is developed, a pattern from which a non-exposed part is removed is obtained.

A fine metal mask (FMM), which is a deposition mask, may be used to form the light-emitting layer 133 of the light-emitting element 130. Further, a spacer may be disposed above the bank layer 137 and made of one of polyimide, photo acrylic, and benzocyclobutene BCB that are transparent organic materials. The spacer is used to inhibit damage caused by contact with the deposition mask disposed on the bank layer 137. The spacer serves to maintain a predetermined distance between the bank layer 137 and the deposition mask.

The light-emitting layer 133 is disposed between the anode 131 and the cathode 135. The light-emitting layer 133 is a layer that emits light by combining electrons and positive holes.

In order to improve luminous efficiency, the light-emitting element 130 may further include at least one of a hole injection layer (HIL), a hole transport layer (HTL), an electron transport layer (ETL), and an electron injection layer (EIL). For example, the hole injection layer and the hole transport layer may be disposed between the anode 131 and the light-emitting layer 133, and the electron transport layer and the electron injection layer may be disposed between the light-emitting layer 133 and the cathode 135. In addition, a hole blocking layer or an electron blocking layer may be disposed on the light-emitting layer 133 to further improve the efficiency in recombining positive holes and electrons.

The cathode 135 is disposed on the light-emitting layer 133 and serves to supply the electrons to the light-emitting layer 133. The cathode 135 needs to supply electrons. Therefore, the cathode 135 may be made of a metallic material such as magnesium (Mg), a silver-magnesium alloy (Ag—Mg), or the like that is an electrically conductive material having a low work function. However, the present specification is not limited thereto.

In case that the display device 100 is a top-emission type, the cathode 135 may be made of transparent conductive oxide such as indium tin oxide (ITO), indium zinc oxide (IZO), indium-tin-zinc oxide (ITZO), zinc oxide (ZnO), and tin oxide (TiO).

The encapsulation layer 139 may be disposed on the light-emitting element 130 and inhibits the thin-film transistor TFT and the light-emitting element 130, which are the constituent elements of the display device 100, from being oxidized or damaged by moisture, oxygen, or impurities introduced from the outside. For example, the encapsulation layer 139 may include a first encapsulation layer 139a, a second encapsulation layer 139b, and a third encapsulation layer 139c. However, the present specification is not limited thereto.

In this case, the first encapsulation layer 139a and the third encapsulation layer 139c may each be made of an inorganic film, and the second encapsulation layer 139b may be made of an organic film. Among the first encapsulation layer 139a, the second encapsulation layer 139b, and the third encapsulation layer 139c, the second encapsulation layer 139b may be thickest and serve as a planarization layer.

The first encapsulation layer 139a may be disposed on the cathode 135 and disposed to be closest to the light-emitting element 130. The first encapsulation layer 139a may be made of an inorganic insulating material that may be deposited at a low temperature. For example, the first encapsulation layer 139a may be made of silicon nitride (SiNx), silicon oxide (SiOx), silicon oxynitride (SiON), aluminum oxide (Al₂O₃), or the like. However, the present specification is not limited thereto. Because the first encapsulation layer 139a is deposited in a low-temperature ambience, it is possible to suppress damage to the light-emitting layer 133 made of an organic material vulnerable to a high-temperature ambience during a deposition process.

The second encapsulation layer 139b may have a smaller area than the first encapsulation layer 139a. In this case, the second encapsulation layer 139b may be formed to expose two opposite ends of the first encapsulation layer 139a. The second encapsulation layer 139b may serve as a buffer for mitigating stress between the layers caused when the display device 100 is bent. The second encapsulation layer 139b may serve to improve the planarization performance.

For example, the second encapsulation layer 139b may be made of an organic insulating material such as acrylic resin, epoxy resin, polyimide, polyethylene, or silicon oxycarbon (SiOC). However, the present specification is not limited thereto. For example, the second encapsulation layer 139b may also be formed in an inkjet manner. However, the present specification is not limited thereto.

The third encapsulation layer 139c may be formed above the glass substrate 110 having the second encapsulation layer 139b to cover a top surface and a side surface of each of the second encapsulation layer 139b and the first encapsulation layer 139a. In this case, the third encapsulation layer 139c may minimize or block the permeation of outside moisture or oxygen into the first encapsulation layer 139a and the second encapsulation layer 139b. For example, the third encapsulation layer 139c may be made of an inorganic insulating material such as silicon nitride (SiNx), silicon oxide (SiOx), silicon oxynitride (SiON), or aluminum oxide (Al₂O₃). However, the present specification is not limited thereto.

A barrier film may be further disposed on the encapsulation layer 139. The barrier film may delay the permeation of oxygen and moisture from the outside. For example, the barrier film may be provided in the form of a film having light transmissivity and double-sided bondability and made of any one insulating material among an olefin-based insulating material, an acrylic-based insulating material, and a silicon-based insulating material. Alternatively, a barrier film made of any one material among cycloolefin polymer (COP), cycloolefin copolymer (COC), and polycarbonate (PC) may be further stacked. However, the present specification is not limited thereto.

A polarizing plate 140 may be disposed on the encapsulation layer 139, selectively transmit light, and reduce the reflection of external light entering the glass substrate 110. Specifically, various metallic materials, which are applied to the thin-film transistor TFT, the lines, the light-emitting element 130, and the like, may be disposed on the glass substrate 110. Therefore, the external light entering the glass substrate 110 may be reflected by the metallic material. The reflection of external light may decrease visibility of the display device 100. In contrast, in case that the polarizing plate 140 is disposed, the polarizing plate 140 may suppress the reflection of external light, thereby improving outdoor visibility of the display device 100. However, the polarizing plate 140 may be excluded in accordance with the implementation of the display device 100. However, the present specification is not limited thereto.

FIG. 3A is a cross-sectional view 100A taken along line A-A′ in FIG. 1 in a state before a bending process. FIG. 3B is a cross-sectional view 100B taken along line A-A′ in FIG. 1 in a state after the bending process. For convenience of illustration, FIGS. 3A and 3B schematically illustrate only a first glass substrate 110a, a second glass substrate 110b, an anti-etching layer 120, the link line LNK, the planarization layer 114, the polarizing plate 140, an upper micro-coating layer 150, and a plurality of lower micro-coating layers 160 among various constituent elements of the display device 100.

With reference to FIGS. 3A and 3B, the glass substrate 110 includes the first glass substrate 110a disposed in the first non-display area NA1 adjacent to the display area AA, and the second glass substrate 110b disposed in the second non-display area NA2 extending from the bending area BA. Meanwhile, the drawings illustrate that the first glass substrate 110a and the second glass substrate 110b are spaced apart from each other with the bending area BA interposed therebetween. However, the first glass substrate 110a and the second glass substrate 110b may be at least partially connected and disposed. The glass substrate 110 includes the first glass substrate 110a and the second glass substrate 110b spaced apart from each other, such that an open portion may be formed between the first glass substrate 110a and the second glass substrate 110b.

Meanwhile, the glass substrate 110 may form the first glass substrate 110a and the second glass substrate 110b by separating a hole and a cell during a process of etching a mother glass substrate. That is, a structure, which enables bezel bending, may be implemented by selectively removing the glass substrate 110 in the bending area BA and simultaneously forming the bending area BA. For example, a process of forming the bending area BA on the glass substrate 110 will be described. A mask is formed on a rear surface of a mother glass substrate, and a hole is formed by removing a part of the mask. In this case, the process of forming the hole may refer to a process of cutting and removing the glass substrate with a laser and separating the hole and the cell from the mother glass substrate. Thereafter, a part of the glass substrate may be primarily etched by using the mask to suit a portion where the bending area BA is to be formed, the mask may be removed, and then the entire rear surface of the glass substrate may be etched. Further, a thickness of the rear surface of the glass substrate may be reduced, the primarily etched portion may be completely removed, and then the bending area BA may be formed on the glass substrate 110.

The first glass substrate 110a may be disposed in the display area AA and the first non-display area NA1 adjacent to the display area AA. The first glass substrate 110a may be disposed adjacent to the bending area BA extending from the first non-display area NA1.

The first glass substrate 110a may include a top surface 110al being in contact with the anti-etching layer 120, a bottom surface 110a2 opposite to the top surface 110a1, and a side surface 110a3 configured to connect an end of the top surface 110al and an end of the bottom surface 110a2 adjacent to the bending area BA.

The end of the top surface 110al of the first glass substrate 110a may be disposed to be closer to the bending area BA than the end of the bottom surface 110a2 to the bending area BA. Therefore, the side surface 110a3 may be defined by an inclined surface that connects the end of the top surface 110al and the end of the bottom surface 110a2. An inclination angle of the side surface 110a3 may be 45 degrees. However, the present specification is not limited thereto. The side surface 110a3 may be configured as a surface inclined or concavely formed.

The second glass substrate 110b is disposed in the second non-display area NA2. That is, the second glass substrate 110b may be disposed in the second non-display area NA2 extending from the bending area BA. Therefore, one end of the second glass substrate 110b may adjoin the bending area BA.

The end of the top surface 110b1 of the second glass substrate 110b may be disposed to be closer to the bending area BA than the end of the bottom surface 110b2 to the bending area BA. An inclination angle of a side surface 110b3 may be 45 degrees. However, the present specification is not limited thereto. The side surface 110b3 adjacent to the bending area BA may be configured as a surface inclined or concavely formed.

The first glass substrate 110a and the second glass substrate 110b may have thicknesses of 0.01 mm to 1.0 mm to maintain the flatness of the top surfaces 110al and 110b1 or block the permeation of moisture or oxygen into the display device 100. In particular, the thickness of each of the first glass substrate 110a and the second glass substrate 110b may be 100 μm. However, the thicknesses of the first glass substrate 110a and the second glass substrate 110b are not limited thereto but may be changed in accordance with the design condition of the display device 100.

A backplate 170 is disposed below the glass substrate 110. The backplate 170 may be used two backplates 170, to be disposed below each of the first glass substrate 110a and the second glass substrate 110b. The backplate 170 may support the first glass substrate 110a and the second glass substrate 110b or serve as a mask to prevent damage during etching process to form a bend area and the first glass substrate 110a and the second glass substrate 110b. For example, the backplate 170 may be a metal material such as stainless steel (SUS) or a plastic material such as polymethylmethacrylate, polycarbonate, polyvinyl alcohol, acrylonitryl-butadiene-styrene, or polyethylene terephthalate. The backplate 170 may be excluded in accordance with the configurations and properties of the display device 100 and the light-emitting element 110.

The anti-etching layer 120 is disposed to overlap the bending area BA. In this case, a bottom surface of the anti-etching layer 120 may be exposed from the first glass substrate 110a and the second glass substrate 110b in the bending area BA. Specifically, the anti-etching layer 120 may be configured to suppress damage caused by etching when the etching process required to form the first glass substrate 110a and the second glass substrate 110b is performed. That is, the anti-etching layer 120 may protect the components positioned above the anti-etching layer 120 during the process in which the side surfaces 110a3 and 110b3 of the first glass substrate 110a and the second glass substrate 110b are formed. Therefore, the anti-etching layer 120 may be disposed to overlap the bending area BA of the display device 100. The anti-etching layer 120 may have a larger area than the bending area BA.

In addition, the anti-etching layer 120 may be disposed in the bending area BA, overlap the top surface 110al of the first glass substrate 110a extending to one side of the bending area BA, and overlap the top surface 110b1 of the second glass substrate 110b extending to the other side of the bending area BA. That is, the anti-etching layer 120 may be disposed on the first glass substrate 110a of the first non-display area NA1 and the second glass substrate 110b of the second non-display area NA2. Further, the anti-etching layer 120 may be disposed only in the non-display area NA corresponding to the bending area BA, or the anti-etching layer 120 may be disposed on a front surface in the first non-display area NA1 including the display area AA. However, the present specification is not limited thereto.

The anti-etching layer 120 may be made of an organic material. Specifically, the anti-etching layer 120 may be made of a material having resistance against a glass etching liquid and a material having corrosion resistance. For example, an etching liquid containing phosphoric acid (H₃PO₄) or hydrofluoric acid (HF) may be used as an etching liquid for etching glass. The anti-etching layer 120 may include any one of a silicone-based organic material, urethane, polyimide, photo acrylic, chromium (Cr), aluminum (Al), platinum (Pt), gold (Au), and nickel (Ni).

In addition, the anti-etching layer 120 may be formed by mechanically spraying a material to a preset position by using a slit coater, an inkjet, a dispenser, or the like. The anti-etching layer 120 may be formed by a patterning process using a photolithography mask. In this case, a thickness of the anti-etching layer 120 may be 1 μm to 5 μm. In particular, the thickness of the anti-etching layer 120 may be 2 μm to 3 μm. However, the present specification is not limited thereto. Meanwhile, in case that the thickness of the anti-etching layer 120 is less than 1 μm, the anti-etching layer 120 is damaged during the glass etching process in the side surfaces 110a3 and 110b3 of the first glass substrate 110a and the second glass substrate 110b are formed. For this reason, the anti-etching layer 120 cannot protect the components positioned above the anti-etching layer 120. In addition, in case that the thickness of the anti-etching layer 120 is more than 5 μm, there is a concern that the anti-etching layer 120 acts as an element that hinders the bending, and the anti-etching layer 120 is damaged by a compressive force during the bending process.

Therefore, the display device 100 includes the anti-etching layer 120 disposed between the first glass substrate 110a, the second glass substrate 110b, and the link line LNK in the bending area BA, such that damage to the display device 100 may be suppressed during the glass etching process in which the side surfaces 110a3 and 110b3 of the first glass substrate 110a and the second glass substrate 110b are formed.

The link line LNK is disposed on the anti-etching layer 120 while traversing the bending area BA. The link line LNK may be disposed on the same layer as the connection electrode CE. The link line LNK may be made of an electrically conductive material. The link line LNK may be made of an electrically conductive material having excellent flexibility in order to reduce the occurrence of cracks when the glass substrate 110 is bent. For example, the link line LNK may be made of an electrically conductive material such as gold (Au), silver (Ag), or aluminum (Al) that has excellent flexibility. The link line LNK may be made of one of various electrically conductive materials used in the display area AA. The link line LNK may be made of an alloy of molybdenum (Mo), chromium (Cr), titanium (Ti), nickel (Ni), neodymium (Nd), copper (Cu), silver (Ag), and magnesium (Mg). Further, the link line LNK may be configured as a multilayer structure including various electrically conductive materials. For example, the link line LNK may be configured as a three-layer structure including titanium (Ti), aluminum (Al), and titanium (Ti). However, the structure of the link line LNK according to the present specification is not limited thereto.

The planarization layer 114 extends in the bending area BA and is disposed on the link line LNK.

The planarization layer 114 may be an organic layer and have a structure in which the second planarization layer 114b is disposed to extend to planarize the top surface of the link line LNK and adjust the thickness of the top surface of the link line LNK. The first planarization layer 114a may not extend. Meanwhile, in case that the connection electrode CE is not disposed and the drain electrode DE is connected directly to the anode 131, the link line LNK may be disposed on the same layer as the drain electrode DE or the source electrode SE and implemented as one planarization layer. Although not illustrated in the drawings, the bank layer 137 may also be disposed to extend in the bending area BA.

The polarizing plate 140 is disposed on the first glass substrate 110a. The polarizing plate 140 may be disposed on the first glass substrate 110a and adjoin the upper micro-coating layer 150 in the first non-display area NA1.

The upper micro-coating layer 150 is disposed to at least partially overlap the first non-display area NA1 and the second non-display area NA2 and disposed on the link line LNK in the bending area BA. The upper micro-coating layer 150 may be disposed to extend in the first non-display area NA1 so as to adjoin the polarizing plate 140.

A tensile force may be applied to the link line LNK disposed on the anti-etching layer 120 during the bending process, which may cause fine cracks. Therefore, the upper micro-coating layer 150 with a small thickness may be applied to the position to be bent, such that the upper micro-coating layer 150 may serve to protect the link line LNK. In this case, the upper micro-coating layer 150 may be made of resin. For example, the upper micro-coating layer 150 may be made of an acrylic-based material or urethane acrylate. However, the present specification is not limited thereto.

The upper micro-coating layer 150 may adjust a neutral surface of the bending area BA. The neutral surface may be an imaginary surface that does not receive stress because a compressive force and a tensile force applied to the structure cancel each other out in case that the structure is bent. In case that two or more structures are stacked, the imaginary neutral surface may be formed between the structures. In case that the entire structures are bent in one direction, the structures disposed in the bending direction based on the neutral surface are compressed by being bent and receive a compressive force. On the contrary, the structures disposed in the direction opposite to the bending direction based on the neutral surface are stretched by being bent and receive a tensile force. Further, because the general structures are weakened in case that the structures receive a tensile force in comparison with a case in which the structures receive a compressive force. For this reason, the probability that cracks occur is high when the structure receives a tensile force.

The anti-etching layer 120 disposed below the neutral surface may be compressed and receive a compressive force, and the link line LNK disposed above the neutral surface may receive a tensile force. For this reason, cracks may be caused by a tensile force. Therefore, the upper micro-coating layer 150 may be positioned on the neutral surface to minimize a tensile force applied to the link line LNK.

Because the upper micro-coating layer 150 is disposed on the bending area BA, the neutral surface may be raised in an upward direction, and the neutral surface may be formed at the same position as the line or positioned at a position higher than the neutral surface, such that no stress may be applied during the bending process, a compressive force may be applied, and the occurrence of cracks may be suppressed. A modulus of the upper micro-coating layer 150 may be 50 MPa to 200 MPa.

The lower micro-coating layer 160 is disposed below the anti-etching layer 120 in the bending area BA. The lower micro-coating layer 160 may be disposed between the first glass substrate 110a and the second glass substrate 110b. Therefore, a portion between the first glass substrate 110a and the second glass substrate 110b may be filled with the lower micro-coating layer 160. Specifically, the lower micro-coating layer 160 is disposed to be in contact with a side surface of the first glass substrate 110a and a side surface of the second glass substrate 110b adjacent to the bending area BA.

The lower micro-coating layer 160 may absorb external impact applied to the space or open portion between the first glass substrate 110a and the second glass substrate 110b corresponding to the bending area BA, thereby improving impact resistance, maintaining a bending shape, and improving durability.

Specifically, the lower micro-coating layers 160 include a first lower micro-coating layer 161 and a second lower micro-coating layer 162. The first lower micro-coating layer 161 is disposed to be in contact with a bottom surface of the anti-etching layer 120 in the bending area BA and disposed to be partially in contact with the side surface of the first glass substrate 110a and the side surface of the second glass substrate 110b. Therefore, a part of the open portion formed between the first glass substrate 110a and the second glass substrate 110b may be filled with the first lower micro-coating layer 161. The second lower micro-coating layer 162 is disposed below the first lower micro-coating layer 161 while corresponding to the bending area BA. The second lower micro-coating layer 162 is disposed to be in contact with a bottom surface of the first lower micro-coating layer 161 and disposed to be partially in contact with the side surface of the first glass substrate 110a and the side surface of the second glass substrate 110b. Therefore, a part of the open portion formed between the first glass substrate 110a and the second glass substrate 110b below the second lower micro-coating layer 162 may be filled with the second lower micro-coating layer 162.

The first lower micro-coating layer 161 may absorb external impact applied to the space or open portion between the first glass substrate 110a and the second glass substrate 110b corresponding to the bending area BA, thereby improving impact resistance. Specifically, the display device 100 according to the implementation of the present disclosure removes the glass substrate 110 and forms the bending area BA in order to implement the bezel area and improve the bending performance. The upper micro-coating layer 150 is formed on the link line LNK while corresponding to the bending area BA and protects the constituent elements of the upper micro-coating layer 150 disposed in the bending area BA. However, because the open portion is formed by removing the glass substrate 110 at a position corresponding to the bending area BA, the bottom surface of the anti-etching layer 120 is exposed in the bending area BA, and a high compressive force is applied to the link line LNK by an edge of the first glass substrate 110a and an edge of the second glass substrate 110b at the lower side during the bending process, which may cause cracks. In addition, because the lower side of the anti-etching layer 120 is empty in the bending area BA, the anti-etching layer 120 is weakened against external impact applied to the bending area BA after the bending process. For this reason, the glass substrate 110, the anti-etching layer 120, and the link line LNK may crack, and the durability may greatly deteriorate. Therefore, the first lower micro-coating layer 161 is disposed below the anti-etching layer 120 while corresponding to the bending area BA, such that the first lower micro-coating layer 161 may absorb external impact applied to the bending area BA from the outside and improve the durability of the display device 100.

The second lower micro-coating layer 162, together with the first lower micro-coating layer 161, may absorb external impact applied to the space or open portion between the first glass substrate 110a and the second glass substrate 110b corresponding to the bending area BA, thereby improving impact resistance. In addition, the second lower micro-coating layer 162 may adjust a bending degree of the bending area BA and reduce a radius of curvature of the bending area BA. In addition, the second lower micro-coating layer 162 may maintain and fix a shape of the bending area BA, thereby improving the durability and reliability of the bending area BA. As described below, unlike the upper micro-coating layer 150 and the first lower micro-coating layer 161 formed by being coated and cured in a flat state that is not bent, the second lower micro-coating layer 162 is formed by being cured after the glass substrate 110 is bent, such that the shape of the bending area BA may be fixed.

The first lower micro-coating layer 161 and the second lower micro-coating layer 162 may each be made of resin. For example, the first lower micro-coating layer 161 and the second lower micro-coating layer 162 may each be made of an acrylic-based material or urethane acrylate. However, the present specification is not limited thereto. In addition, the first lower micro-coating layer 161 and the second lower micro-coating layer 162 may each be made of a curable material capable of being cured by UV rays, visible light, or the like. The first lower micro-coating layer 161 and the second lower micro-coating layer 162 may be made of the same material. However, the present specification is not limited thereto. The first lower micro-coating layer 161 and the second lower micro-coating layer 162 may be made of different materials.

The first lower micro-coating layer 161 and the second lower micro-coating layer 162 may be separately formed by an application process and a curing process. Various resin application methods, e.g., slit coating, jetting, or the like may be used as a method of applying the first lower micro-coating layer 161 and the second lower micro-coating layer 162. Next, the curing process is performed to determine curing degrees and moduli of the first lower micro-coating layer 161 and the second lower micro-coating layer 162.

Meanwhile, the first lower micro-coating layer 161 and the second lower micro-coating layer 162 may be formed by separate processes. Specifically, the first lower micro-coating layer 161 may be formed by preparing a panel on which the upper micro-coating layer 150 is formed on the link line LNK before a folding process, applying a first lower micro-coating composition onto the bottom surface of the anti-etching layer 120 so as to correspond to the bending area BA so that the first lower micro-coating composition comes into contact with the bottom surface of the anti-etching layer 120, and then performing a UV curing process. Next, a second lower micro-coating composition is applied onto the bottom surface of the anti-etching layer 120 so as to correspond to the bending area BA so that the second lower micro-coating composition comes into contact with the bottom surface of the anti-etching layer 120. Thereafter, the second lower micro-coating layer 162 is formed by bending the bottom surface 110b2 of the second glass substrate 110b so that the bottom surface 110b2 of the second glass substrate 110b faces the bottom surface 110a2 of the first glass substrate 110a and then curing the applied second lower micro-coating composition by irradiating the applied second lower micro-coating composition with UV rays. With reference to FIG. 3B, with the above-mentioned process, the bottom surface of the second lower micro-coating layer 162 may have an arc shape in the bending direction, like the first lower micro-coating layer 161 or the anti-etching layer 120. That is, at least a part of the bottom surface of the second lower micro-coating layer 162 may have an arc shape so as to correspond to the bending area BA.

In this case, the first lower micro-coating layer 161 and the second lower micro-coating layer 162 may be made of different materials and/or formed under different curing conditions so as to have different physical properties. For example, in case that the first lower micro-coating layer 161 and the second lower micro-coating layer 162 are made of the same material, the first lower micro-coating layer 161 and the second lower micro-coating layer 162 are formed under different conditions during the curing process, such that the first lower micro-coating layer 161 and the second lower micro-coating layer 162 may have different physical properties.

The second lower micro-coating layer 162 may have a larger modulus than the first lower micro-coating layer 161. As described above with reference to the method of forming the lower micro-coating layer 160, the curing process is performed after the second lower micro-coating layer 162 is bent, and the first lower micro-coating layer 161 may be more cured at a higher level to maintain the bending shape. Therefore, the second lower micro-coating layer 162 may have a larger modulus than the first lower micro-coating layer 161, maintain the bending shape, and absorb impact from the outside. For example, the modulus of the first lower micro-coating layer 161 may be 10⁶ to 10⁸ Pa, and the modulus of the second lower micro-coating layer 162 may be 10⁶ to 10⁹ Pa. However, the present specification is not limited thereto.

A thickness of the lower micro-coating layer 160 may be 30% to 100% or 50% to 80% of a thickness of the glass substrate 110. For example, the thickness of the lower micro-coating layer 160 may be 50 μm to 300 μm. In this case, the thickness of the lower micro-coating layer 160 is a sum of the thickness of the first lower micro-coating layer 161 and the thickness of the second lower micro-coating layer 162. In case that the thickness of the lower micro-coating layer 160 is smaller than 30% of the thickness of the glass substrate 110, external impact absorption performance may deteriorate, and high stress is applied to the anti-etching layer 120 and the link line LNK during the bending process, which may cause cracks. In case that the thickness of the lower micro-coating layer 160 is larger than the thickness of the glass substrate 110, the bending process may not be easily performed, and bending stress may increase. Meanwhile, the bending stress may be lowest in case that the thickness of the lower micro-coating layer 160 is about 50% of the thickness of the glass substrate 110.

A thickness ratio between the first lower micro-coating layer 161 and the second lower micro-coating layer 162 may be 1:2 to 2:1. However, the present specification is not limited thereto. In addition, in case that the thickness of the first lower micro-coating layer 161 is about 50% of the thickness of the glass substrate 110, the thickness of the second lower micro-coating layer 162 may be smaller than the thickness of the first lower micro-coating layer 161. In case that the thickness ratio between the first lower micro-coating layer 161 and the second lower micro-coating layer 162 satisfies the above-mentioned range, the performance in absorbing external impact and maintaining the bending shape may be implemented.

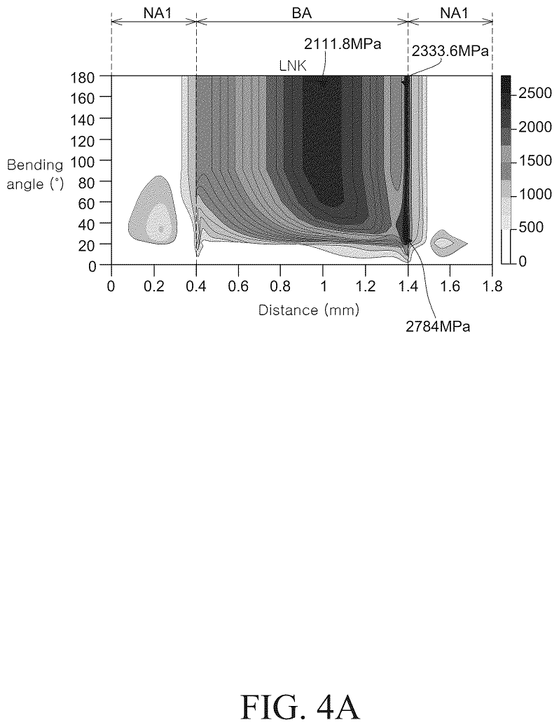

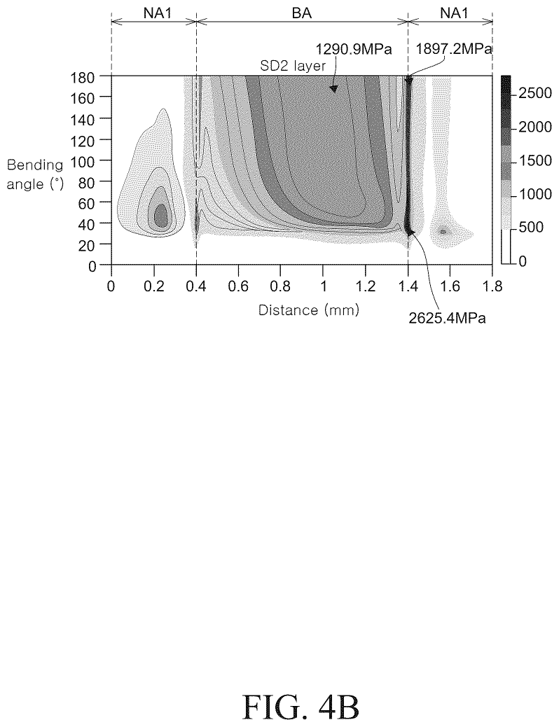

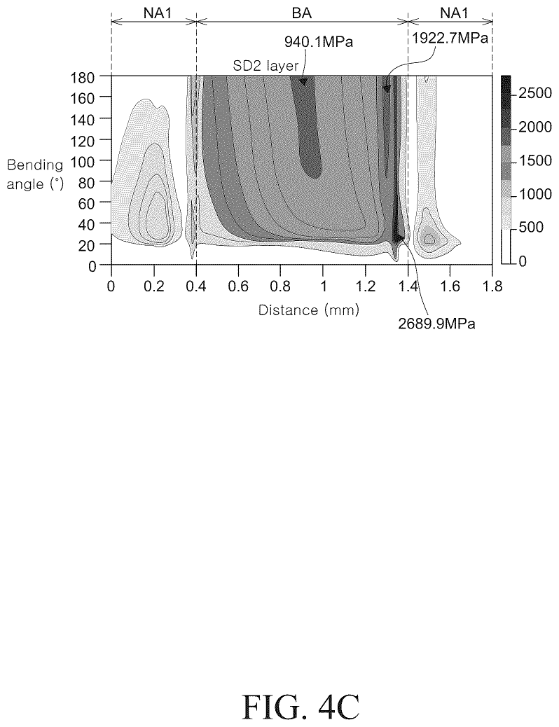

Hereinafter, an effect of the display device according to the implementation of the present specification will be described with reference to FIGS. 4A to 4C.

FIGS. 4A to 4C illustrate results of simulations on stress on the display device in accordance with the thicknesses of the lower micro-coating layer. For example, the common conditions of the display device 100 simulated and evaluated in FIGS. 4A to 4C are as shown in Table 1.

TABLE 1

| Constituent Element | Thickness (μm) | Modulus (MPa) |
|---|---|---|
| Glass substrate 110 | 150 | 60 |
| Anti-etching layer 120 | 2.0 | 7.4 |
| First planarization layer 114a | 2.0 | — |
| Link line LNK | 0.7 | 475 |
| Second planarization layer 114b | 2.0 | — |
| Bank layer 137 | 2.5 | — |
| Upper micro-coating layer 150 | 150 | 0.109 |
| Lower micro-coating layer 160 | Changed | 0.109 |

In the graph, the X-axis indicates a distance (Distance (mm)) from the first glass substrate 110a to the second glass substrate 110b of the display device 100, the Y-axis indicates a bending angle (Bending angle (°)), and contour lines to be measured indicate von Mises stress (MPa). In this case, a distance of 0 to 0.4 mm along the X-axis is a left portion of the display device 100 (a portion of the first glass substrate 110a), a distance of 0.4 mm to 1.6 mm is the bending area BA, and a distance of 1.4 mm to 1.8 mm is a right portion (a portion of the second glass substrate 110b). The highest stress is applied to the link line in the right bending area portion of the display device during the bezel bending process. In this case, different types of stress, i.e., the tension and compression represent directions and stress, but the von Mises stress is implemented in the form of a scalar having no direction. Therefore, the von Mises stress refers to a complex stress value such as the tension and compression. Therefore, when the von Mises stress reaches yield stress, the material may be interpreted as yielding. However, when the von Mises stress decreases, the material may be interpreted as moving away from a yield stress value.

FIG. 4A illustrates values of the von Mises stress applied to the link line in accordance with bending angles in a top plan view and a cross-sectional view of a display device according to an experimental example in which a sum of the thicknesses of the lower micro-coating layers 160 is 25 μm. FIG. 4B illustrates the values of the von Mises stress applied to the link line in accordance with bending angles in a top plan view and a cross-sectional view of a display device according to an experimental example in which a sum of the thicknesses of the lower micro-coating layer 160 is 75 μm. FIG. 4C illustrates values of the von Mises stress applied to the link line in accordance with bending angles in a top plan view and a cross-sectional view of a display device according to an experimental example in which a sum of the thicknesses of the lower micro-coating layer 160 is 100 μm. In this case, the first lower micro-coating layer and the second lower micro-coating layer of the lower micro-coating layer 160 are set to have the same thickness.

With reference to FIG. 4A, it can be ascertained that in the experimental example in which a sum of the thicknesses of the lower micro-coating layer 160 is 25 μm, the value of the von Mises stress applied to the link line LNK positioned at the end of the second glass substrate 110b is 2333.6 MPa when a portion of about 1.4 mm of the display device is bent by 180° during the bezel bending process, and the value of the von Mises stress applied to the link line LNK positioned at the end of the second glass substrate 110b is 2784 MPa when the portion of the display device is bent by 20°. In addition, with reference to FIG. 4B, it can be ascertained that in the experimental example in which a sum of the thicknesses of the lower micro-coating layer 160 is 75 μm, the value of the von Mises stress applied to the link line LNK positioned at the end of the second glass substrate 110b is 1897.2 MPa when a portion of about 1.4 mm of the display device is bent by 180° during the bezel bending process, and the value of the von Mises stress applied to the link line LNK positioned at the end of the second glass substrate 110b is 2625.4 MPa when the portion of the display device is bent by 20°. In addition, with reference to FIG. 4C, it can be ascertained that in the experimental example in which a sum of the thicknesses of the lower micro-coating layer 160 is 100 μm, the value of the von Mises stress applied to the link line LNK positioned at the end of the second glass substrate 110b is 1922.7 MPa when a portion of about 1.4 mm of the display device is bent by 180° during the bezel bending process, and the value of the von Mises stress applied to the link line LNK positioned at the end of the second glass substrate 110b is 2678.9 MPa when the portion of the display device is bent by 20°.

When FIGS. 4A to 4C are compared, it can be ascertained that in the experimental example in FIGS. 4B and 4C in which the sum of the thicknesses of the lower micro-coating layers 160 is 50% and 66.7% based on the first glass substrate 110, the maximum stress is further reduced in comparison with the experimental example in FIG. 4A in which the sum of the thicknesses of the lower micro-coating layers 160 is 12.5%.

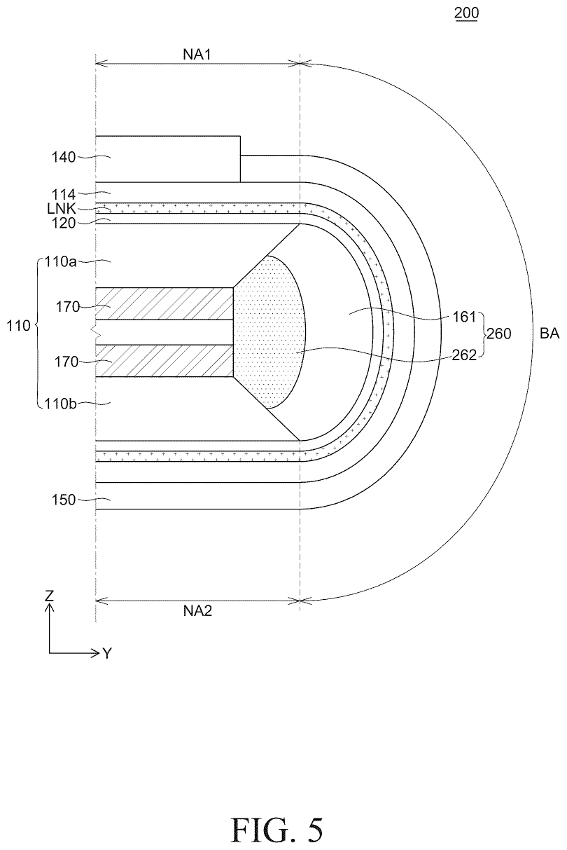

FIG. 5 is a cross-sectional view of a display device according to another implementation of the present specification. For convenience of illustration, FIG. 5 schematically illustrates only the first glass substrate 110a, the second glass substrate 110b, the anti-etching layer 120, the link line LNK, the planarization layer 114, the polarizing plate 140, the upper micro-coating layer 150, and lower micro-coating layers 260. A display device 200 illustrated in FIG. 5 is substantially identical to the display device 100 illustrated in FIGS. 1 to 3B, except for the lower micro-coating layers 260. Therefore, repeated descriptions of the identical components will be omitted or briefly described.

With reference to FIG. 5, in the display device 200 according to another implementation of the present specification, the lower micro-coating layers 260 include the first lower micro-coating layer 161 and a second lower micro-coating layer 262. Because the first lower micro-coating layer 161 of the display device 200 illustrated in FIG. 5 is substantially identical to the first lower micro-coating layer 161 of the display device 100 illustrated in FIGS. 1 to 3B, a repeated description thereof will be omitted or briefly described.

A bottom surface of the second lower micro-coating layer 262 may be formed to extend in a direction (Z-axis direction) perpendicular to a direction (Y-axis direction) in which the glass substrate extends. That is, the bottom surface of the second lower micro-coating layer 262 may have a flat shape in a thickness direction (Z-axis direction). With reference to FIG. 5, the bottom surface of the second lower micro-coating layer 262 is in contact with an end of a bottom surface of the first glass substrate 110a and an end of a bottom surface of the second glass substrate 110b. Specifically, the bottom surface of the second lower micro-coating layer 262 may be formed to be consistent with an imaginary straight line that connects the end of the bottom surface of the first glass substrate 110a adjacent to the bending area BA and the end of the bottom surface of the second glass substrate 110b adjacent to the bending area BA. A shape of the second lower micro-coating layer 262 illustrated in FIG. 5 may be implemented by a difference between manufacturing processes.

Specifically, the second lower micro-coating layer 162 of the display device 100 illustrated in FIGS. 1 to 3B is formed by applying the second lower micro-coating composition onto the bottom surface of the second lower micro-coating layer 162 before the bending process and performing the curing process after the bending process. Therefore, the bottom surface of the second lower micro-coating layer 162 of the display device 100 illustrated in FIG. 3B has an arc shape after the bending process. On the contrary, in the case of the display device 200 illustrated in FIG. 5, the first lower micro-coating layer 161 is formed by applying the first lower micro-coating composition onto the bottom surface of the anti-etching layer 120 so as to correspond to the bending area BA and curing the first lower micro-coating composition. Next, the display device 200 is bent so that the bottom surface of the second glass substrate 110b faces the bottom surface of the first glass substrate 110a. Thereafter, the second lower micro-coating layer 262 is formed by applying the second lower micro-coating composition onto the bottom surface of the anti-etching layer 120 so as to correspond to the bending area BA while maintaining the bent state so that the second lower micro-coating composition comes into contact with the bottom surface of the anti-etching layer 120 and then curing the applied second lower micro-coating composition by irradiating the second lower micro-coating composition with UV rays. That is, the display device 200 illustrated in FIG. 5 is different in manufacturing processes from the display device 100 illustrated in FIG. 3B in that the second micro-coating composition is applied in the bent state, and then the second micro-coating composition is cured. Therefore, the bottom surface of the second lower micro-coating layer 262 of the display device 200 illustrated in FIG. 5 may have a flat shape.

In the display device 200 illustrated in FIG. 5, the contact area between the second lower micro-coating layer 262, the side surface of the first glass substrate 110a, and the side surface of the second glass substrate 110b may be maximized. Therefore, it is possible to effectively maintain the bending shape. Furthermore, the second lower micro-coating layer 262 is also in contact with the backplate 170 positioned on the bottom surface of the first glass substrate 110a and the bottom surface of the second glass substrate 110b, such that external impact applied to the bending area BA may be effectively dispersed to the first glass substrate 110a, the second glass substrate 110b, and the backplate 170.

Therefore, the display device 200 illustrated in FIG. 5 may maintain the bending shape and improve impact resistance against external impact.

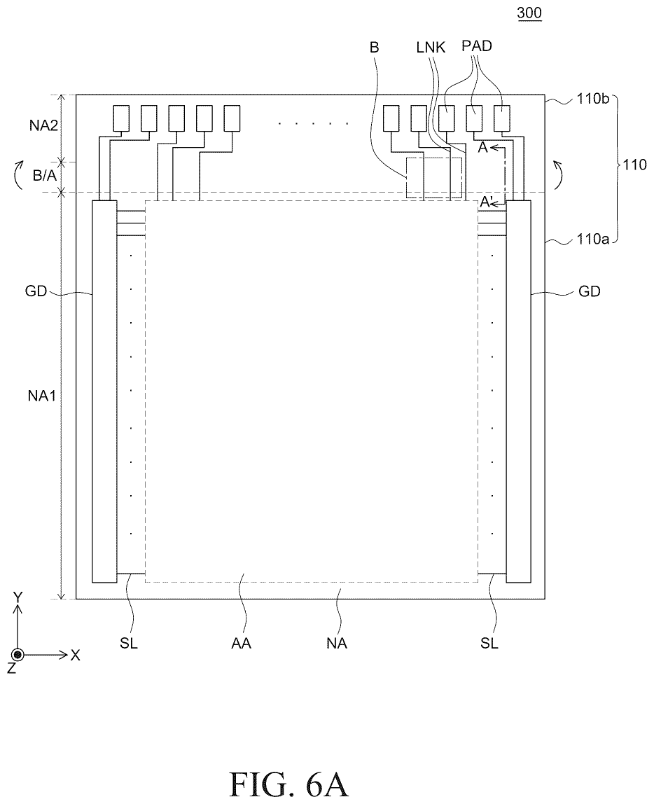

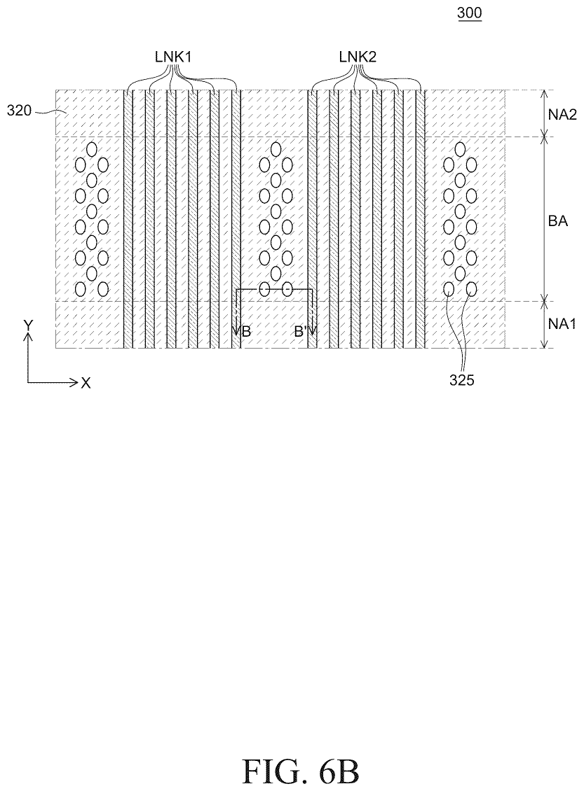

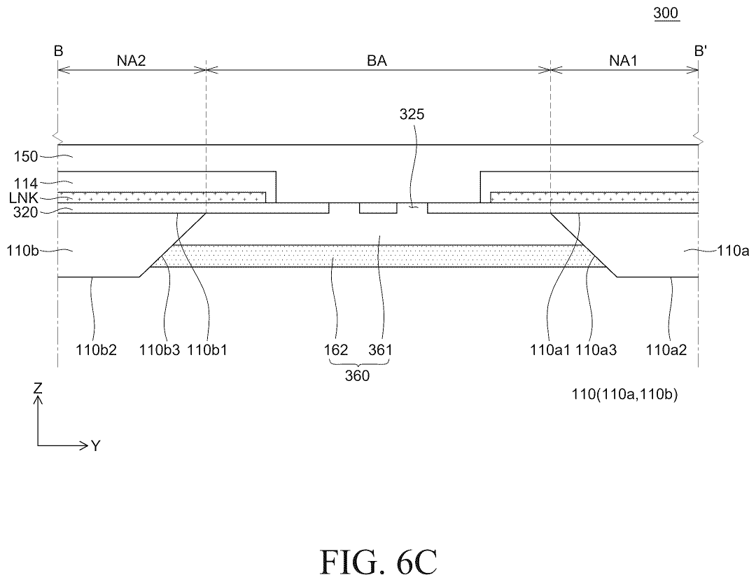

FIGS. 6A to 6C are views illustrating a display device according to still another implementation of the present specification. FIG. 6A is a top plan view of the display device according to still yet another implementation of the present specification. FIG. 6B is an enlarged view of area B in FIG. 6A. FIG. 6C is a cross-sectional view taken along line B-B′ in FIG. 6B in a state before the bending process. For convenience of illustration, FIG. 6B schematically illustrates only the anti-etching layer 120 and the link lines LNK. In addition, for convenience of illustration, FIG. 6C schematically illustrates only the first glass substrate 110a, the second glass substrate 110b, the anti-etching layer 320, the link line LNK, the planarization layer 114, the polarizing plate 140, the upper micro-coating layer 150, and lower micro-coating layers 360. A display device 300 illustrated in FIGS. 6A to 6C is substantially identical to the display device 100 illustrated in FIGS. 1 to 3B, except for an anti-etching layer 320 and a lower micro-coating layer 360. Therefore, repeated descriptions of the identical components will be omitted or briefly described.

With reference to FIGS. 6B and 6C, the anti-etching layer 320 is disposed to overlap the bending area BA. In this case, the top surface of the anti-etching layer 320 is in contact with the link line LNK, and the bottom surface of the anti-etching layer 320 is in contact with the lower micro-coating layer 360.

The anti-etching layer 320 includes a plurality of holes 325. The plurality of holes 325 is formed through at least a part of the anti-etching layer 320 in the bending area BA. The plurality of holes 325 are filled with a first lower micro-coating layer 361 or the upper micro-coating layer 150. The plurality of holes 325 serve to disperse stress, which is applied to the link line LNK by the bending shape, to the upper micro-coating layer 150 or the lower micro-coating layer 360 having a large volume.

With reference to FIG. 6B, the plurality of holes 325 are disposed in the bending area BA. In this case, the plurality of holes 325 may be disposed between a plurality of unit link lines. Specifically, the link line LNK disposed in the bending area BA includes the plurality of unit link lines. For example, the unit link lines include a plurality of first link lines LNK1 or a plurality of second link lines LNK2. The plurality of first link lines LNK1 and the plurality of second link lines LNK2 may be link lines configured to transmit different signals or link lines configured to transmit the same signal. For example, the plurality of first link lines LNK1 may be link lines configured to transmit touch signals to a touch electrode, and the plurality of second link lines LNK2 may be link lines configured to transmit driving signals to a driving element. Therefore, the plurality of holes 325 may be disposed between the plurality of first link lines LNK1 and the plurality of second link lines LNK2 or disposed at the left side of the first link line LNK1 or the right side of the second link line LNK2.

With reference to FIG. 6C, the insides of the plurality of holes 325 may be filled with the first lower micro-coating layer 361. Therefore, the first lower micro-coating layer 361 and the upper micro-coating layer 150 may be in direct contact with each other by the plurality of holes 325. However, unlike the configuration illustrated in FIG. 6C, the insides of the plurality of holes 325 may be filled with the upper micro-coating layer 150. This configuration may vary depending on the order of the manufacturing process.

For example, in the display device illustrated in FIGS. 6A to 6C, the anti-etching layer 320, the link line LNK, and the upper micro-coating layer 150 are sequentially stacked on the glass substrate 110, and then a partial area of the anti-etching layer 320 is irradiated with laser beams, such that the plurality of holes 325 are formed in the anti-etching layer 320. Thereafter, the first lower micro-coating layer 361 is formed, such that it is possible to implement the structure in which the plurality of holes 325 are filled with the first lower micro-coating layer 361. Unlike the configuration illustrated in FIG. 6C, the anti-etching layer 320 and the link line LNK are formed on the glass substrate 110, the first lower micro-coating layer is formed first, and then the plurality of holes may be formed in the anti-etching layer. Thereafter, the upper micro-coating layer is formed, such that it is possible to implement the structure in which the insides of the plurality of holes are filled with the upper micro-coating layer.

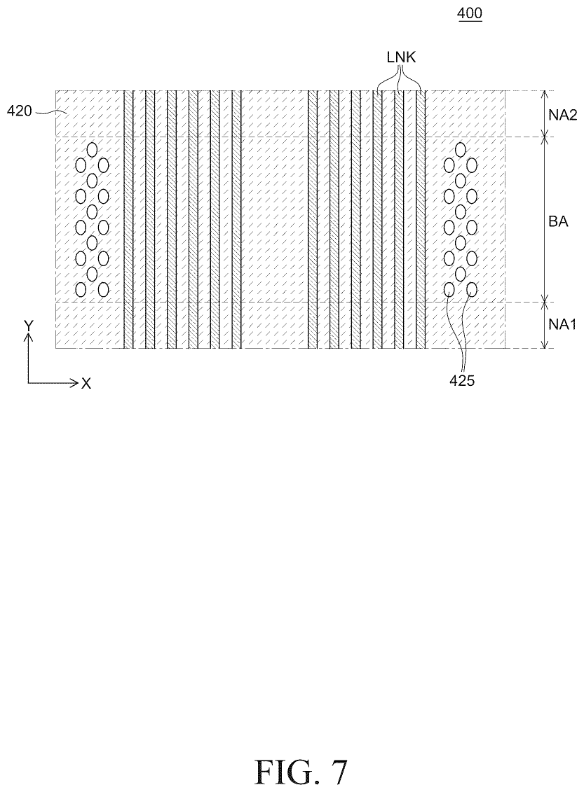

FIG. 7 is a top plan view of a display device according to yet another implementation of the present specification. For the convenience of illustration, FIG. 7 schematically illustrates only an anti-etching layer 420 and link lines. A display device 400 illustrated in FIG. 7 is substantially identical to the display device 300 illustrated in FIG. 6C, except for a plurality of holes 425. Therefore, repeated descriptions of the identical components will be omitted or briefly described.

With reference to FIG. 7, the anti-etching layer 420 includes the plurality of holes 425. The plurality of holes 425 serve to inhibit cracks, which occur during the bending process, from propagating into the display device 400 from an edge of the display device 400 that is an outer side of the display device 400.

Specifically, the plurality of holes is disposed outside the link lines LNK in the bending area BA. That is, the plurality of holes 425 may be disposed in a plurality of columns in an area between the edge of the display device 400 and the link line LNK disposed at an outermost side. Therefore, a propagation route of a crack occurring at the edge of the display device 400 is lengthened by the holes 425 arranged in the plurality of columns, and the stress propagates to the upper micro-coating layer or the lower micro-coating layer that fills the plurality of holes 425, which may suppress the occurrence of a crack in the link line LNK.

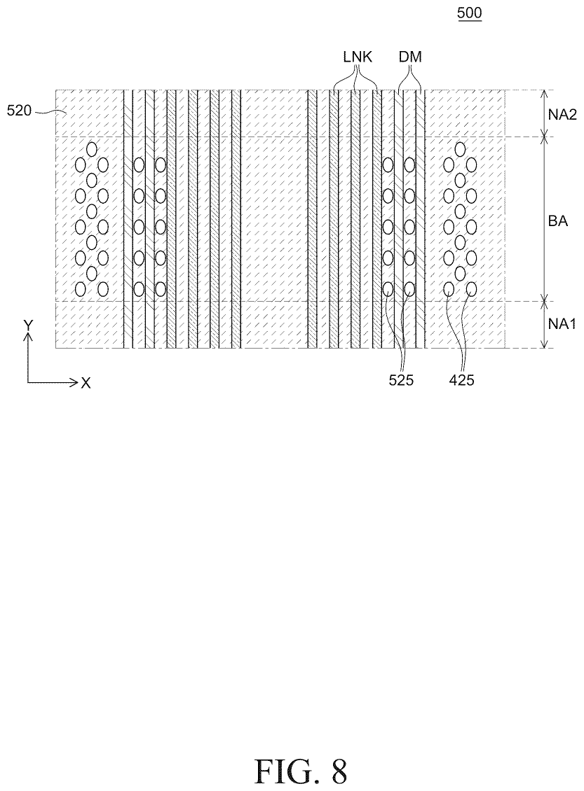

FIG. 8 is a top plan view of a display device according to still yet another implementation of the present specification. For the convenience of illustration, FIG. 8 schematically illustrates only an anti-etching layer 520, the link lines LNK, and dummy lines DM. A display device 500 illustrated in FIG. 8 is substantially identical to the display device 400 illustrated in FIG. 7, except for the dummy line DM and a plurality of dummy holes 525. Therefore, repeated descriptions of the identical components will be omitted or briefly described.

With reference to FIG. 8, the dummy line DM is disposed outside the link line LNK. The dummy line DM may be made of the same material as the link line LNK and disposed on the same layer as the link line LNK. The dummy line DM serves as a barrier that inhibits cracks from propagating into the display device 500 from the edge of the display device 500 that is the outer side of the display device 500.

With reference to FIG. 8, the anti-etching layer 520 includes the plurality of holes 425. The plurality of holes 425 serve to inhibit cracks, which occur during the bending process, from propagating into the display device from the edge of the display device that is the outer side of the display device. The plurality of holes 425 are disposed outside the link lines LNK in the bending area BA.

Meanwhile, the display device 500 illustrated in FIG. 8 may further include the plurality of auxiliary holes (e.g., dummy holes) 525 disposed between the plurality of dummy lines DM or disposed between the link lines LNK and the dummy lines DM. Like the plurality of holes 425, because of the plurality of auxiliary holes 525, the propagation route of the crack occurring at the edge of the display device 500 is further lengthened by the auxiliary holes 525 arranged in the plurality of columns, and the stress propagates to the upper micro-coating layer or the lower micro-coating layer that fills the plurality of auxiliary holes 525, which may suppress the occurrence of a crack in the link line LNK.

With the dummy lines DM and the plurality of auxiliary holes 525, the display device 500 illustrated in FIG. 8 may inhibit the crack from propagating from the edge of the display device 500 and improve the durability of the display device 500.

The example implementations of the present disclosure can also be described as follows:

According to an aspect of the present disclosure, there is provided a display device. The display device comprises a display area and a non-display area comprising a first non-display area adjacent to the display area, a bending area extending from at least one side of the first non-display area, and a second non-display area extending from one side of the bending area. The display device comprises a first glass substrate disposed in the display area, a second glass substrate disposed in the second non-display area, an anti-etching layer disposed to overlap the bending area, a link line disposed on the anti-etching layer while traversing the bending area, an upper micro-coating layer disposed to at least partially overlap the first non-display area and the second non-display area and disposed on the link line in the bending area, a first lower micro-coating layer disposed below the anti-etching layer in the bending area and a second lower micro-coating layer disposed below the first lower micro-coating layer in the bending area.

An overall thickness of the first and second lower micro-coating layers may be smaller than a thickness of the first and second glass substrates.

The overall thickness of the first and second lower micro-coating layers may be 50% to 80% of the thickness of the first and second glass substrates.

The second lower micro-coating layer may be different in curing degree and modulus from the first lower micro-coating layer.

A Young's modulus of the second lower micro-coating layer may be 10⁶ to 10⁹ Pa.

A thickness of the second lower micro-coating layer may be smaller than a thickness of the first lower micro-coating layer.

The display device may be bent such that the second glass substrate is disposed on a bottom surface of the first glass substrate so as to overlap the first glass substrate. The second lower micro-coating layer may be disposed to be in contact with one side surface of the first glass substrate directed toward the bending area and one side surface of the second glass substrate directed toward the bending area.

At least a part of a bottom surface of the second lower micro-coating layer may define an arc shape so as to correspond to the bending area.

A bottom surface of the second lower micro-coating layer may be in contact with an end of a bottom surface of the first glass substrate directed toward the bending area and an end of a bottom surface of the second glass substrate directed toward the bending area and has a flat shape.

An end of a top surface of each of the first and second glass substrates may be disposed to be closer to the bending area than an end of a bottom surface of each of the first and second glass substrates to the bending area.

A side surface of each of the first and second glass substrates, which is adjacent to the bending area, may be formed as a surface inclined or concavely formed.

The anti-etching layer may be disposed on the first glass substrate in the first non-display area and disposed on the second glass substrate in the second non-display area. A bottom surface of the anti-etching layer may be exposed between the first glass substrate and the second glass substrate in the bending area.

A thickness of the anti-etching layer may be 1 μm to 5 μm.

The anti-etching layer may comprise a plurality of holes disposed in the bending area. The first lower micro-coating layer and the upper micro-coating layer may be in contact with each other by the plurality of holes.

The link line may comprise a plurality of first link lines and a plurality of second link lines that traverse the bending area. The plurality of holes may be disposed between the plurality of first link lines and the plurality of second link lines.

The link line may comprise a plurality of link lines extending to traverse the bending area. The plurality of holes may be disposed outside the plurality of link lines in a direction perpendicular to a direction in which the plurality of link lines extends. The plurality of holes may be not disposed between the plurality of link lines.

The display device may further comprise a plurality of dummy link lines disposed outside the plurality of link lines in the direction perpendicular to the direction in which the plurality of link lines extends. The anti-etching layer may further comprise a plurality of dummy holes disposed between the plurality of dummy link lines or between the plurality of dummy link lines and the plurality of link lines.

Although the example implementations of the present disclosure have been described in detail with reference to the accompanying drawings, the present disclosure is not limited thereto and may be embodied in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, which comprises a display area and a non-display area comprising a first non-display area adjacent to the display area, a bending area extending from at least one side of the first non-display area, and a second non-display area extending from one side of the bending area, the display device comprising:
a first glass substrate disposed in the display area;
a second glass substrate disposed in the second non-display area;
an anti-etching layer disposed to overlap the bending area;
a link line disposed on the anti-etching layer and traversing the bending area;
an upper micro-coating layer disposed on the link line in the bending area and disposed to at least partially overlap the first non-display area and the second non-display area;
a first lower micro-coating layer disposed below the anti-etching layer in the bending area; and
a second lower micro-coating layer disposed below the first lower micro-coating layer in the bending area.

2. The display device of claim 1, wherein a combined thickness of the first and second lower micro-coating layers is smaller than a thickness of each of the first and second glass substrates.

3. The display device of claim 2, wherein the combined thickness of the first and second lower micro-coating layers is 50% to 80% of the thickness of each of the first and second glass substrates.

4. The display device of claim 1, wherein the second lower micro-coating layer is different in curing degree and modulus from the first lower micro-coating layer.

5. The display device of claim 4, wherein a Young's modulus of the second lower micro-coating layer is 10⁶ to 10⁹ Pa.

6. The display device of claim 2, wherein a thickness of the second lower micro-coating layer is smaller than a thickness of the first lower micro-coating layer.

7. The display device of claim 1, wherein the display device is configured to be bent such that the second glass substrate is disposed on a bottom surface of the first glass substrate so as to overlap the first glass substrate, and
wherein the second lower micro-coating layer is disposed to be in contact with one side surface of the first glass substrate that faces toward the bending area, and
wherein the second lower micro-coating layer is disposed to be in contact with one side surface of the second glass substrate that faces toward the bending area.

8. The display device of claim 7, wherein at least a part of a bottom surface of the second lower micro-coating layer defines an arc shape corresponding to the bending area.

9. The display device of claim 7, wherein a bottom surface of the second lower micro-coating layer is in contact with an end of a bottom surface of the first glass substrate that faces toward the bending area,
wherein the bottom surface of the second lower micro-coating layer is in contact with an end of a bottom surface of the second glass substrate that faces toward the bending area, and
wherein the bottom surface of the second lower micro-coating layer has a flat shape.

10. The display device of claim 1, wherein an end of a top surface of the first glass substrate is disposed to be closer to the bending area than an end of a bottom surface of the first glass substrate, and
wherein an end of a top surface of the second glass substrate is disposed to be closer to the bending area than an end of a bottom surface of the second glass substrate.

11. The display device of claim 10, wherein a side surface of the first glass substrate and a side surface of the second glass substrate, which are adjacent to the bending area, are formed as a surface inclined or concavely formed.

12. The display device of claim 1, wherein the anti-etching layer is disposed on the first glass substrate in the first non-display area and is disposed on the second glass substrate in the second non-display area, and
wherein a bottom surface of the anti-etching layer is exposed between the first glass substrate and the second glass substrate in the bending area.

13. The display device of claim 12, wherein a thickness of the anti-etching layer is 1 μm to 5 μm.

14. The display device of claim 12, wherein the anti-etching layer comprises a plurality of holes disposed in the bending area, and
wherein the first lower micro-coating layer and the upper micro-coating layer are in contact with each other through the plurality of holes.

15. The display device of claim 14, wherein the link line comprises a plurality of first link lines and a plurality of second link lines that traverse the bending area, and
wherein the plurality of holes is disposed between the plurality of first link lines and the plurality of second link lines.

16. The display device of claim 14, wherein the link line comprises a plurality of link lines extending to traverse the bending area,
wherein the plurality of holes is disposed outside the plurality of link lines in a direction perpendicular to a direction in which the plurality of link lines extends, and
wherein the plurality of holes is not disposed between the plurality of link lines.

17. The display device of claim 16, further comprising:
a plurality of dummy link lines disposed outside the plurality of link lines in the direction perpendicular to the direction in which the plurality of link lines extends,
wherein the anti-etching layer further comprises a plurality of dummy holes disposed between the plurality of dummy link lines or between the plurality of dummy link lines and the plurality of link lines.
